(19) United States
(12) Patent Application Publication
(10) Pub. No.: US 2026/0031806 A1
(43) Pub. Date: Jan. 29, 2026

(54) SEMICONDUCTOR DEVICE AND SWITCHING DEVICE

(71) Applicant: ROHM CO., LTD., Kyoto-shi (JP)

(72) Inventors: Koshiro NAGASATO, Kyoto-shi (JP); Koki MISHIMA, Kyoto-shi (JP)

(21) Appl. No.: 19/271,928

(22) Filed: Jul. 17, 2025

(30) Foreign Application Priority Data
Jul. 24, 2024 (JP) 2024-118486

(51) Int. Cl. H03K 17/082

(52) U.S. Cl. CPC H03K 17/0822

(57) ABSTRACT

In a target transistor, a first conductive electrode, a second conductive electrode, and a control electrode are respectively connected to first, second, and third wirings. The control circuit responds to an input control signal so as to supply a high side voltage or a low side voltage to the third wiring, thereby controlling the target transistor to be ON or OFF. If the low side voltage is lower than the voltage of the second wiring by a predetermined threshold voltage or more, an overvoltage signal in an asserted state is output. When the overvoltage signal in the asserted state is output, the control circuit supplies the low side voltage to the third wiring regardless of the input control signal, and a protection switching element, which is disposed between the second wiring and a fourth wiring applied with the low side voltage, is set to be ON.

### CROSS REFERENCE TO RELATED APPLICATIONS

The present invention claims priority under 35 U.S.C. § 119 to Japanese Patent Application No. 2024-118486 filed Jul. 24, 2024, the entire contents of which are hereby incorporated by reference.

### BACKGROUND OF THE INVENTION

### Field of the Invention

The present disclosure relates to a semiconductor device and a switching device.

### Description of Related Art

A semiconductor device is widely used for controlling a state of a target transistor. One example of this type of semiconductor device may be referred to as a gate driver (see Patent Document 1).

Patent Document 1: JP-A-2018-14549

### BRIEF DESCRIPTION OF THE DRAWINGS

FIG. 1 is a diagram illustrating the basic configuration of a signal transmission device.

FIG. 2 is a diagram illustrating the basic structure of a transformer chip.

FIG. 3 a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a structural diagram of a signal transmission device according to an application structure.

FIG. 11 is an overall structural diagram of a system including the signal transmission device according to the application structure.

FIG. 12 is an external perspective view of the signal transmission device of FIG. 11.

FIG. 13 is a diagram illustrating a structural example of the resistor circuit of FIG. 11.

FIG. 14 is a diagram illustrating another structural example of the resistor circuit of FIG. 11.

FIG. 15 is a diagram illustrating a structural example of the negative voltage generation circuit of FIG. 11.

FIG. 16 is a diagram illustrating a relationship between a primary side control signal and a secondary side control signal in the signal transmission device of FIG. 11.

FIG. 17 is an explanatory diagram of an operation of a secondary side circuit during a period where an overvoltage signal state is maintained in a negated state, according to the signal transmission device of FIG. 11.

FIG. 18 is an explanatory diagram of a VEE2_OVLO function, according to the signal transmission device of FIG. 11.

FIG. 19 is a timing chart for explaining an operation when a negative voltage abnormality is detected, according to the signal transmission device of FIG. 11.

FIG. 20 is a diagram illustrating a structural example of a protection switching element, according to the signal transmission device of FIG. 11.

FIG. 21 is a diagram illustrating another structural example of the protection switching element, according to the signal transmission device of FIG. 11.

FIG. 22 is a structural diagram of a system including a switching device, according to an embodiment of the present disclosure.

### DETAILED DESCRIPTION OF THE PREFERRED EMBODIMENTS

### Signal Transmission Device (Basic Configuration)

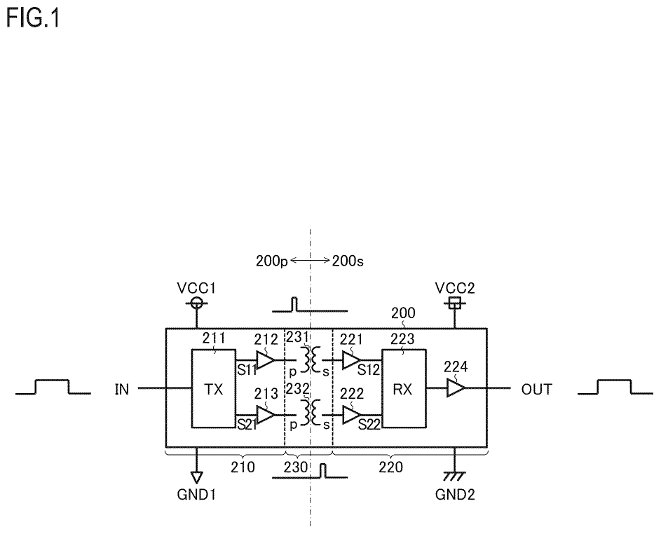

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drivers the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

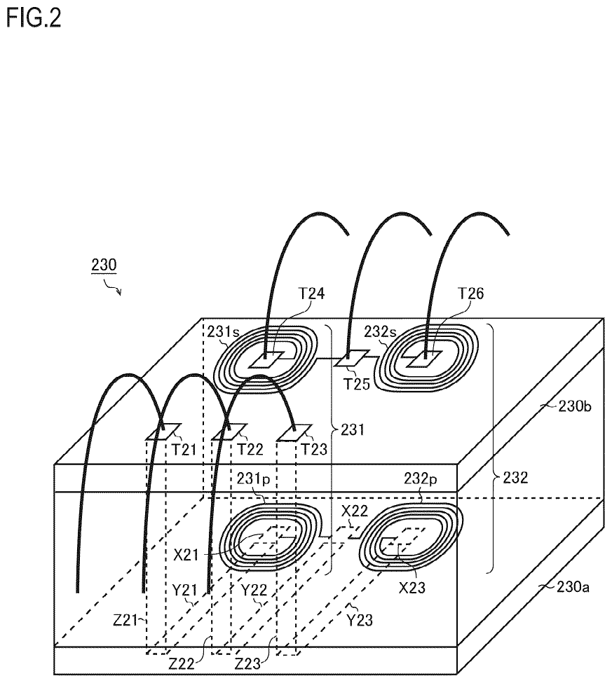

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 231s are both formed in a second wiring layer (the upper layer in the diagram) 230b in the transformer chip 230. The secondary coil 23 1s is disposed right above the primary coil 231p and faces the primary coil 231p; the secondary coil 232s is disposed right above the primary coil 232p and faces the primary coil 232p.

The primary coil 23 1p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

### Transformer Chip (Two-Channel Type)

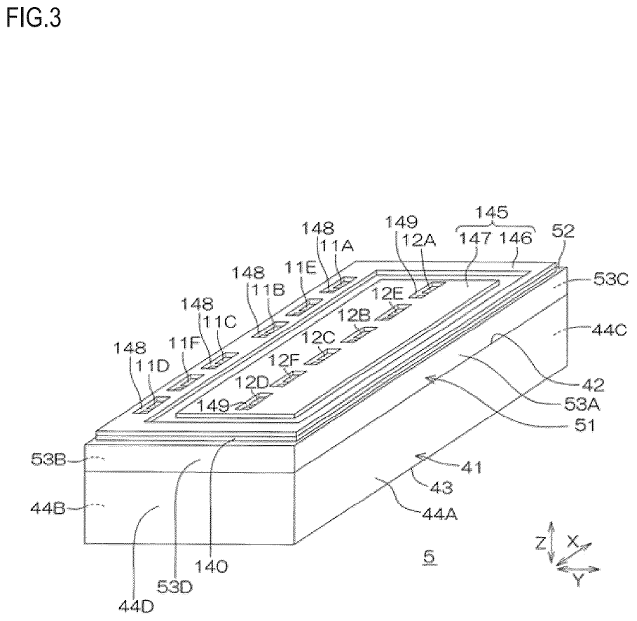

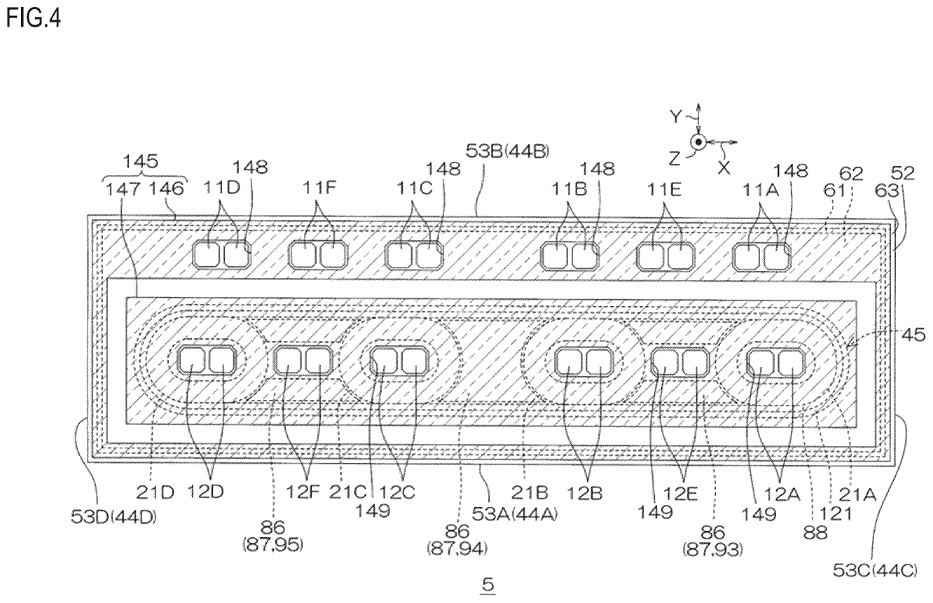

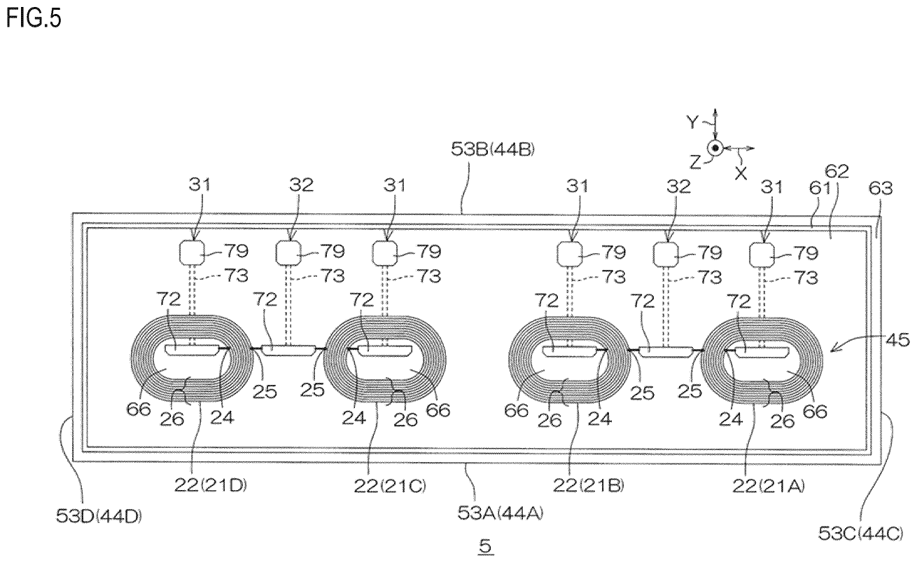

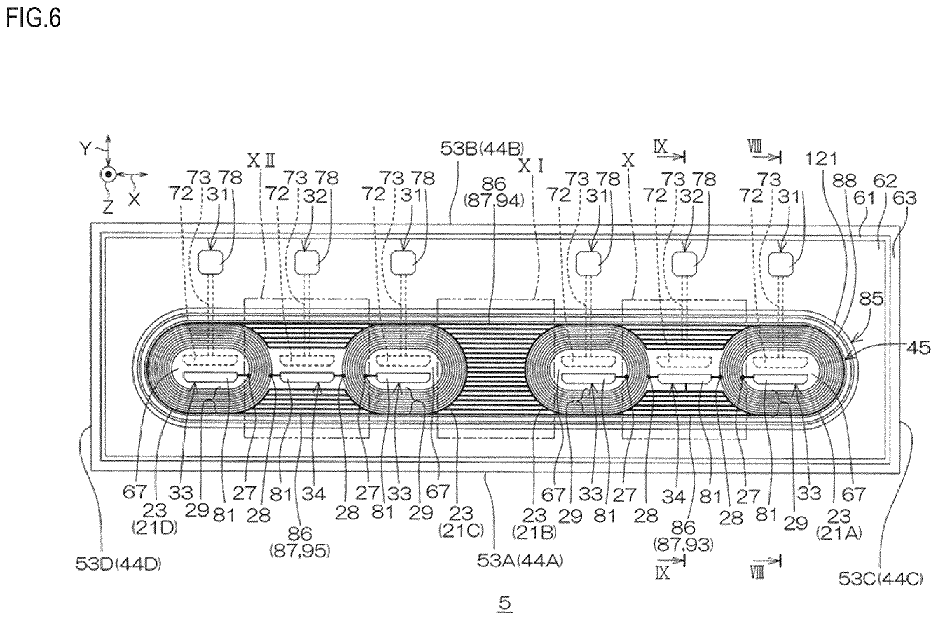

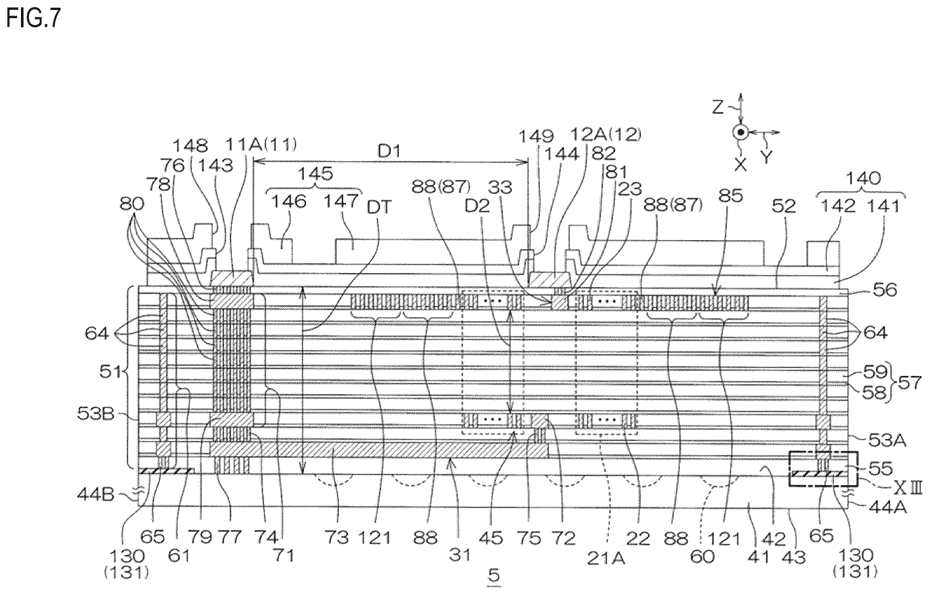

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6.

Referring to FIGS. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D includes a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41, and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIGS. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layer 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The body layer is embedded in a recessed space defined by the barrier layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23, and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layer 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island, and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance DI can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41, and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIGS. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D. In the embodiment, the sealing conductor 61 is formed in a quadrangular ring shape (specifically, a rectangular ring shape) as seen in a plan view. Thus, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41, and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductor 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

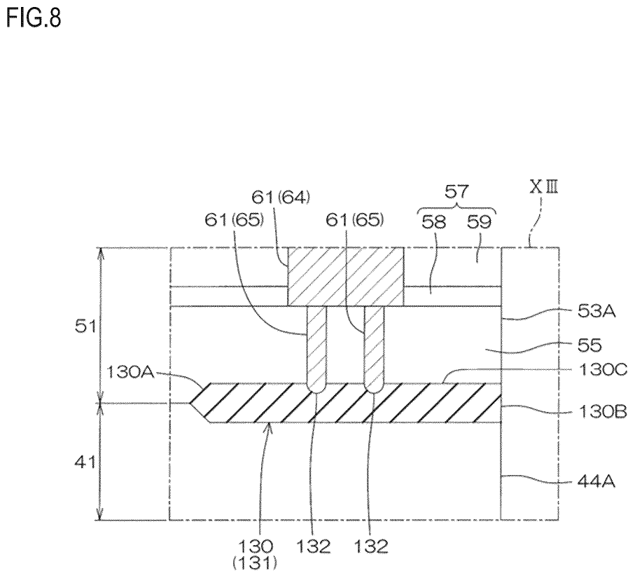

Referring to FIG. 7 and FIG. 8, the semiconductor device 5 further includes a separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlapping parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with a first embodiment (except those associated with the dummy pattern 85).

That is, in a case where a voltage is applied to the second functional device 60 via the low-and high-potential terminals 11 and 12, it is possible suppress unnecessary conduction between the high-potential terminal 12 and the sealing conductor 61. Likewise, in a case where a voltage is applied to the second functional device 60 via the low-and high-potential terminals 11 and 12, it is possible suppress unnecessary conduction between the low-potential terminal 11 and the sealing conductor 61.

The embodiment described above deals with an example where a second functional device 60 is formed. The second functional device 60 however is not essential, and can be omitted.

The embodiment described above deals with an example where a dummy pattern 85 is formed. The dummy pattern 85 however is not essential, and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

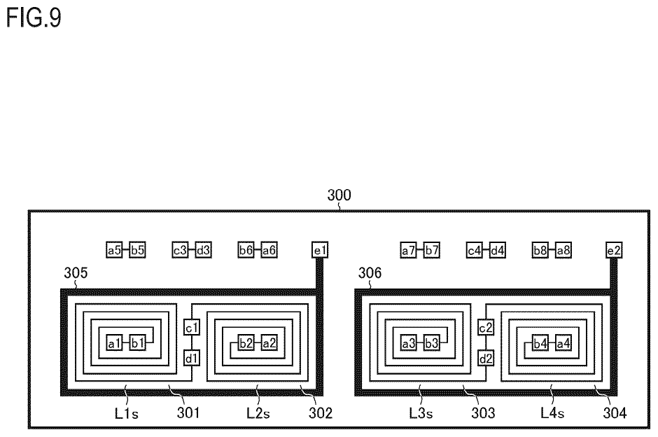

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively, and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads al to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 302, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate, to obtain a desired withstand voltage between the primary and secondary coils. The first and second guard rings 305 and 306 are however not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Signal Transmission Device (Application Structure)

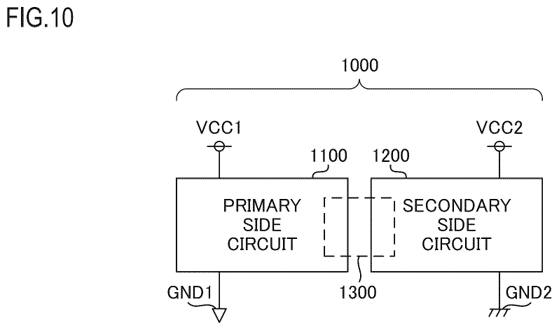

FIG. 10 illustrates a structural diagram of a signal transmission device 1000. The signal transmission device 1000 is a signal transmission device according to an application structure, and may be formed by utilizing the structure of the signal transmission device 200 described above (see FIG. 1 and the like). The signal transmission device 1000 may be considered as one form of the signal transmission device 200.

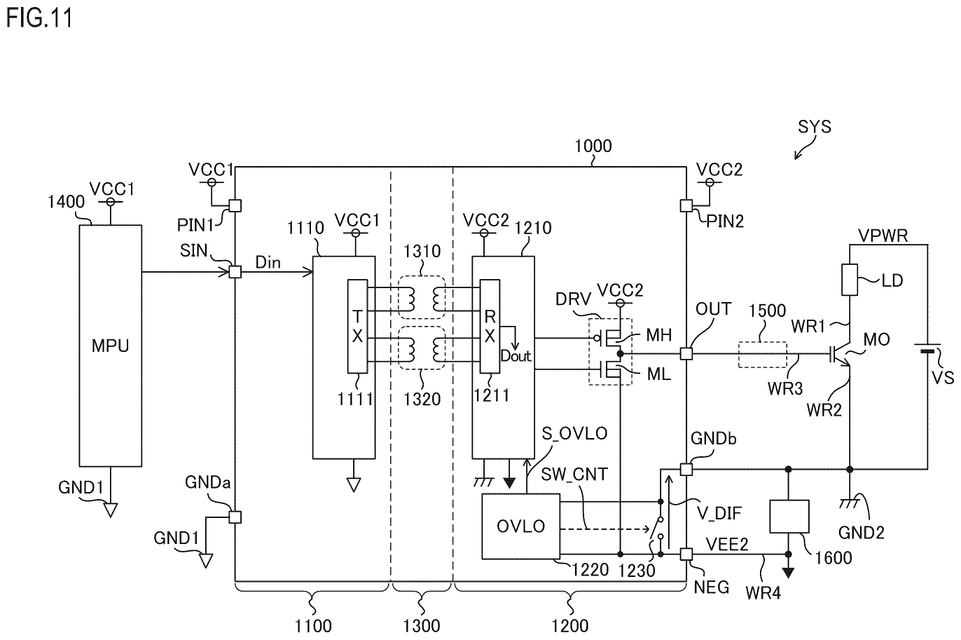

Note that in this specification, for simple description, by writing a symbol or code representing information, signal, physical quantity, functional section, circuit, element, component, or the like, a name of the information, signal, physical quantity, functional section, circuit, element, component, or the like corresponding to the symbol or code may be abbreviated or shortened. For instance, a first signal processing circuit denoted by “1110” described later (see FIG. 11) may be referred to as a first signal processing circuit 1110, or may be referred to as a signal processing circuit 1110, which indicate the same one.

Some terms and expressions are described below. A level means a level (height) of a potential (electric potential), and for an arbitrary noted signal or voltage, high level has a higher potential than low level. In an arbitrary noted signal or voltage, switching from low level to high level may be referred to as a rising edge, and switching from high level to low level may be referred to as a falling edge.

For an arbitrary transistor constituted as a field-effect transistor (FET) such as a MOSFET, ON state means a state where the transistor is conducting between the drain and source, while OFF state means a state where the transistor is nonconducting (cut off) between the drain and source of the transistor. The same is true for a transistor (such as an IGBT) that is not classified as an FET. A MOSFET is understood to be an enhancement type MOSFET, unless otherwise noted. MOSFET is an abbreviation of “metal-oxide-semiconductor field-effect transistor”. In addition, unless otherwise noted, in an arbitrary MOSFET, it may be considered that the backgate is short-circuited to the source. Hereinafter, for an arbitrary transistor, ON state and OFF state may be simply expressed as ON and OFF. In addition, for an arbitrary transistor, a period during which the transistor is in ON state is referred to as an ON period, while a period during which the transistor is in OFF state is referred to as an OFF period.

For an arbitrary signal having a signal level of high level or low level, a period during which the level of the signal is high level is referred to as a high level period, while a period during which the level of the signal is low level is referred to as a low level period. The same is true for an arbitrary voltage having a voltage level of high level or low level.

Connection between a plurality of parts forming a circuit, such as arbitrary circuit elements, wirings, and nodes, may be understood to mean electric connection, unless otherwise noted.

When arbitrary two voltages to be compared are voltages v1 and v2, “v1>v2” means that the voltage v1 is higher than the voltage v2, “v1<v2” means that the voltage v1 is lower than the voltage v2, and “v1=v2” means that the value of the voltage v1 is the same as the value of the voltage v2. The same is true for other expressions including a physical quantity other than voltage.

As illustrated in FIG. 10, the signal transmission device 1000 includes a primary side circuit 1100 and a secondary side circuit 1200. The signal transmission device 1000 is provided with an insulation circuit 1300 including a plurality of insulation elements. The primary side circuit 1100 and the secondary side circuit 1200 are insulated from each other. Each of the insulation elements in the insulation circuit 1300 is disposed between the primary side circuit 1100 and the secondary side circuit 1200. The insulation circuit 1300 is a circuit that insulates in a DC manner between the primary side circuit 1100 and the secondary side circuit 1200, while transmitting a signal in the primary side circuit 1100 to the secondary side circuit 1200. A power supply source for the transmission is the primary side circuit 1100, and hence in detail, the primary side circuit 1100 drives the insulation elements in the insulation circuit 1300 so that a signal in the primary side circuit 1100 is transmitted to the secondary side circuit 1200.

The primary side circuit 1100 and the secondary side circuit 1200 respectively correspond to the primary circuit system 200p and the secondary circuit system 200s of FIG. 1. It may be considered that the primary side circuit 1100 is one form of the primary circuit system 200p, and that the secondary side circuit 1200 is one form of the secondary circuit system 200s. The primary side circuit 1100 can be formed of the controller chip 210 (see FIG. 1 and the like), and the secondary side circuit 1200 can be formed of the driver chip 220 (see FIG. 1 and the like). The insulation circuit 1300 can be formed of the transformer chip 230 (see FIG. 1 and the like).

A ground in the primary side circuit 1100 is referred to as a ground GND1. The ground GND1 has a reference potential in the primary side circuit 1100. A conductor part having the reference potential in the primary side circuit 1100 is the ground GND1. In the primary side circuit 1100, a voltage shown without a specific reference indicates a potential with respect to the ground GND1. The power supply voltage VCC1 (see FIG. 1, too) is supplied to the primary side circuit 1100. The primary side circuit 1100 is driven on the basis of the power supply voltage VCC1, with respect to the potential of the ground GND1.

A ground in the secondary side circuit 1200 is referred to as a ground GND2. The ground GND2 has a reference potential in the secondary side circuit 1200. A conductor part having the reference potential in the secondary side circuit 1200 is the ground GND2. In the secondary side circuit 1200, a voltage shown without a specific reference indicates a potential with respect to the ground GND2. The power supply voltage VCC2 (see FIG. 1, too) is supplied to the secondary side circuit 1200. The secondary side circuit 1200 is driven on the basis of the power supply voltage VCC2, with respect to the potential of the ground GND2. The ground GND1 and the ground GND2 are insulated from each other.

FIG. 11 illustrates an overall structure of a system SYS including the signal transmission device 1000. The system SYS is provided with, in addition to the signal transmission device 1000, a microprocessor unit (MPU) 1400, a resistor circuit 1500, a negative voltage generation circuit 1600, a target transistor MO, a load LD, and a voltage source VS. The target transistor MO is an N-channel type insulated gate bipolar transistor (IGBT). However, an N-channel type MOSFET may be used as the target transistor MO. The signal transmission device 1000 has a function of driving the gate of the target transistor MO, and the signal transmission device 1000 can be referred to as a gate driving device (insulation gate driver). The MPU 1400 is an example of an external device disposed outside of the signal transmission device 1000. The signal transmission device 1000 is disposed between the MPU 1400 and the target transistor MO.

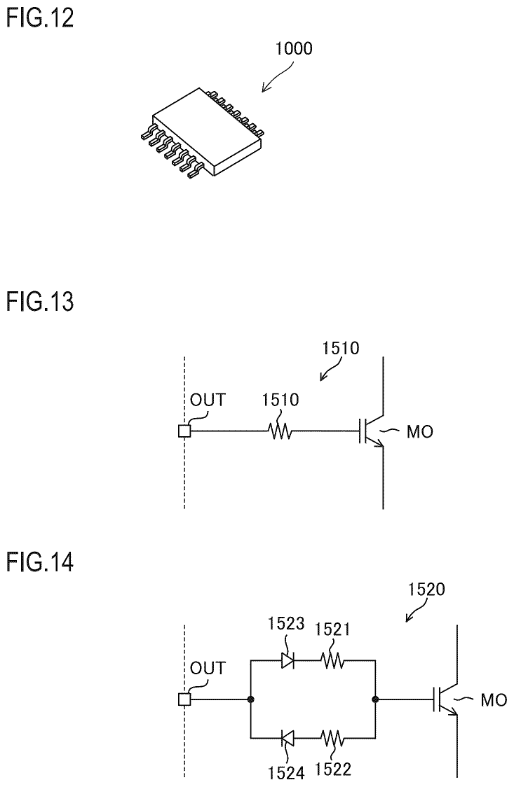

FIG. 12 is an external perspective view of the signal transmission device 1000. The signal transmission device 1000 is an electronic component (semiconductor device) equipped with a plurality of semiconductor chips, a case (package) housing the plurality of semiconductor chips, and a plurality of external terminals exposed from the case to the outside of the signal transmission device 1000. The plurality of semiconductor chips are sealed in the case (package) made of resin, and thus the signal transmission device 1000 is formed. Note that the number of the external terminals of the signal transmission device 1000 and a type of the case of the signal transmission device 1000 illustrated in FIG. 12 are merely an example, and they can be arbitrarily designed. FIG. 11 illustrates power supply terminals PIN1 and PIN2, a signal input terminal SIN, ground terminals GNDa and GNDb, an output terminal OUT, and a negative power supply terminal NEG, as a part of the plurality of external terminals provided to the signal transmission device 1000. Other external terminals are also provided to the signal transmission device 1000.

In FIG. 11, a not-shown external voltage source supplies the power supply voltage VCC1 to the power supply terminal PIN1. In FIG. 11, another not-shown external voltage source supplies the power supply voltage VCC2 to the power supply terminal PIN2. The ground terminal GNDa is connected to the ground GND1. The ground terminal GNDb is connected to the ground GND2. The MPU 1400 is driven on the basis of the power supply voltage VCC1 with respect to the ground GND1.

An external structure of the signal transmission device 1000 is described. The output terminal OUT and the gate of the target transistor MO are connected to a wiring WR3, and are connected to each other via the wiring WR3. The resistor circuit 1500 is inserted in series to the wiring WR3 disposed between the output terminal OUT and the gate of the target transistor MO. The resistor circuit 1500 includes a resistance component that functions as the gate resistance of the target transistor MO. For instance, the resistor circuit 1500 may be a resistor circuit 1510 illustrated in FIG. 13. The resistor circuit 1510 consists of a single resistor 1511. If the resistor circuit 1500 is the resistor circuit 1510, a first terminal of the resistor 1511 is connected to the output terminal OUT, and a second terminal of a resistor 1512 is connected to the gate of the target transistor MO. Alternatively, for example, the resistor circuit 1500 may be a resistor circuit 1520 illustrated in FIG. 14. The resistor circuit 1520 includes resistors 1521 and 1522, and diodes 1523 and 1524. If the resistor circuit 1500 is the resistor circuit 1520, the output terminal OUT is connected to the anode of the diode 1523 and the cathode of the diode 1524, the cathode of the diode 1523 is connected to a first terminal of the resistor 1521, a second terminal of the resistor 1521 is connected to the gate of the target transistor MO, the anode of the diode 1524 is connected to a first terminal of the resistor 1522, and a second terminal of the resistor 1522 is connected to the gate of the target transistor MO.

The load LD is inserted between an application terminal of a power supply voltage VPWR and the target transistor MO. In the structural example of FIG. 11, the first terminal of the load LD is connected to the application terminal of the power supply voltage VPWR, and a second terminal of the load LD is connected to the collector of the target transistor MO. The emitter of the target transistor MO is connected to the ground GND2. The wiring connected to the collector of the target transistor MO is referred to as a wiring WR1, and the wiring connected to the emitter of the target transistor MO is referred to as a wiring WR2. The wiring WR2 has the potential of the ground GND2. The power supply voltage VPWR has a potential higher than the ground GND2 by a predetermined level. A current loop, which passes the voltage source VS that generates the power supply voltage VPWR with respect to the potential of the ground GND2, the load LD, the target transistor MO, and the ground GND2, is formed. During the ON period of the target transistor MO, a current based on the power supply voltage VPWR flows through the load LD and the target transistor MO (the current flows in the current loop described above). During the OFF period of the target transistor MO, the current through the load LD and the target transistor MO is not generated (the current does not flow in the current loop described above). The ground terminal GNDb is connected to the emitter of the target transistor MO.

The negative voltage generation circuit 1600 is connected to a wiring WR4, and is connected to the ground GND2 (therefore, is connected to the wiring WR2 and the ground terminal GNDb). In addition, the negative power supply terminal NEG is connected to the wiring WR4. The voltage of the wiring WR4 is referred to as a voltage VEE2. On the condition that a protection switching element 1230 described later is OFF, the negative voltage generation circuit 1600 generates the voltage VEE2 on the wiring WR4 with respect to the potential of the wiring WR2, the voltage VEE2 being lower than the potential of the wiring WR2.

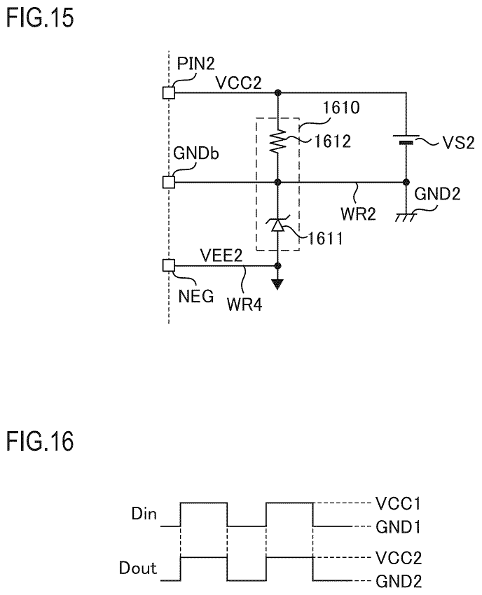

FIG. 15 illustrates a negative voltage generation circuit 1610 that is an example of the negative voltage generation circuit 1600. The negative voltage generation circuit 1610 includes a zener diode 1611 and a resistor 1612. A voltage source VS2 illustrated in FIG. 15 is an external voltage source disposed outside of the signal transmission device 1000, and has a negative side terminal connected to the ground GND2 and a positive side terminal connected to the power supply terminal PIN2, so as to output the power supply voltage VCC2 from the positive side terminal, with respect to the potential of the negative side terminal. If the negative voltage generation circuit 1600 is the negative voltage generation circuit 1610, the anode of the zener diode 1611 is connected to the negative power supply terminal NEG (therefore, is connected to the wiring WR4), the cathode of the zener diode 1611 and a first terminal of the resistor 1612 are commonly connected to the ground terminal GNDb (therefore, are commonly connected to the wiring WR2), and a second terminal of the resistor 1612 is connected to the power supply terminal PIN2. As a result, if the protection switching element 1230 described later is OFF, a voltage lower than the potential of the ground GND2 by a zener voltage of the zener diode 1611 is applied as the voltage VEE2 to a negative side terminal NEG. Note that a current loop is formed from the positive side terminal of the voltage source VS2 to the negative side terminal of the voltage source VS2, through the resistor 1612, the zener diode 1611 and the negative side terminal NEG, via the secondary side circuit 1200 and the ground terminal GNDb, so that the negative voltage VEE2 is generated when a current flows in the current loop.

An internal structure of the signal transmission device 1000 of FIG. 11 is described. The signal transmission device 1000 includes the first signal processing circuit 1110 as a structural element of the primary side circuit 1100, and includes a second signal processing circuit 1210, an overvoltage detection circuit 1220, the protection switching element 1230, and a driver DRV as structural elements of the secondary side circuit 1200, and includes transformers 1310 and 1320 as structural elements of the insulation circuit 1300.

The first signal processing circuit 1110 is driven on the basis of the power supply voltage VCCI with respect to the potential of the ground GND1. The MPU 1400 supplies a control signal Din to the signal input terminal SIN, and the control signal Din from the MPU 1400 is received by the first signal processing circuit 1110 through the signal input terminal SIN. The control signal Din is a control signal in the primary side circuit 1100, and has high level or low level. In the control signal Din, high level has the potential of the power supply voltage VCC1, while low level has the potential of the ground GND1. A waveform shaping circuit such as a Schmitt buffer may be disposed between the signal input terminal SIN and the first signal processing circuit 1110. Note that the MPU 1400 and the first signal processing circuit 1110 may be connected to each other in such a manner that they can perform bidirectional communication. The bidirectional communication between the MPU 1400 and the first signal processing circuit 1110 may be serial communication with a serial peripheral interface (SPI). Alternatively, in the bidirectional communication, it may be possible to use an interface of I²C (Inter-Integrated Circuit) or Microwire.

The first signal processing circuit 1110 includes a transmission circuit 1111. The transmission circuit 1111 is connected to each primary side coil of the transformers 1310 and 1320. The second signal processing circuit 1210 includes a reception circuit 1211. The reception circuit 1211 is connected to each secondary side coil of the transformers 1310 and 1320. Using the transformers 1310 and 1320, the control signal Din is transmitted from the transmission circuit 1111 to the reception circuit 1211 in an insulation form. In other words, the transmission circuit 1111 supplies a transmission pulse signal to each primary side coil of the transformers 1310 and 1320 in accordance with the control signal Din, and the reception circuit 1211 restores the control signal Din on the basis of a reception pulse signal generated across both ends of each secondary side coil of the transformers 1310 and 1320. The restored control signal Din is referred to as a control signal Dout. The control signals Din and Dout are respectively examples of a primary side control signal and a secondary side control signal. The control signal Dout is a control signal in the secondary side circuit 1200, and has high level or low level. In the control signal Dout, high level has the potential of the power supply voltage VCC2, and low level has the potential of the ground GND2. Note that the transformers 1310 and 1320 respectively have the same structure as the transformers 231 and 232 described above (see FIG. 1 and the like). It can also be understood that the transformer 1310 is the transformer 231 itself, and that the transformer 1320 is the transformer 232 itself.

In addition, although not particularly illustrated, it may be possible that the second signal processing circuit 1210 can also transmit a signal to the first signal processing circuit 1110 in an insulation form. In other words, it may be possible to dispose a secondary side transmission circuit having the same structure as the transmission circuit 1111 in the second signal processing circuit 1210, while to dispose a primary side reception circuit having the same structure as the reception circuit 1211 in the first signal processing circuit 1110, and to dispose another transformer that transmits a signal from the secondary side transmission circuit to the primary side reception circuit in an insulation form, in the insulation circuit 1300. Further, if an abnormality (e.g., a negative voltage abnormality described later) is detected in the secondary side circuit 1200, it is possible to transmit an abnormality detection signal indicating that an abnormality has been detected, from the secondary side transmission circuit to the primary side reception circuit through the another transformer described above, and when the first signal processing circuit 1110 receives the abnormality detection signal, it can send a predetermined error signal to the MPU 1400.

FIG. 16 illustrates a relationship between the control signals Din and Dout. In an initial state, the control signals Din and Dout have low level. The transmission circuit 1111 responds to a rising edge of the control signal Din so as to supply a transmission pulse signal (pulse-like current) to the primary side coil of the transformer 1310, thereby generates a reception pulse signal (electromotive force) across both ends of the secondary side coil of the transformer 1310, and the reception circuit 1211 generates a rising edge in the control signal Dout, on the basis of the reception pulse signal in the secondary side coil of the transformer 1310. The transmission circuit 1111 responds to a falling edge in the control signal Din, so as to supply a transmission pulse signal (pulse-like current) to the primary side coil of the transformer 1320, thereby generates a reception pulse signal (electromotive force) across both ends of the secondary side coil of the transformer 1320, and the reception circuit 1211 generates a falling edge in the control signal Dout, on the basis of the reception pulse signal in the secondary side coil of the transformer 1320. The relationship between the level of the control signal Din and the level of the control signal Dout may be opposite to that described above, and here, it is supposed that the reception circuit 1211 is configured so that the control signal Dout has high level in the high level period of the control signal Din, and that the control signal Dout has low level in the low level period of the control signal Din (for simple description, signal delay is omitted).

Note that the insulation circuit 1300 has an arbitrary structure, as long as the secondary side circuit 1200 can obtain the control signal Dout described above, by transmitting the control signal Din to the secondary side circuit 1200 in an insulation form. Therefore, the insulation element in the insulation circuit 1300 may be a capacitor.

The second signal processing circuit 1210 drives the gate of the target transistor MO, by controlling a state of the driver DRV in accordance with the control signal Dout. When the gate of the target transistor MO is driven, the gate voltage of the target transistor MO is controlled, and the state of the target transistor MO is set to ON or OFF. The driver DRV has transistors MH and ML connected to each other in series. The transistor MH is a high side transistor constituted of a P-channel type MOSFET, while the transistor ML is a low side transistor constituted of an N-channel type MOSFET. The source of the transistor MH is connected to the application terminal of the power supply voltage VCC2. The drains of the transistors MH and ML are commonly connected to the output terminal OUT. The source of the transistor ML is connected to the negative power supply terminal NEG. Therefore, the voltage at the source of the transistor ML is the voltage VEE2.

The second signal processing circuit 1210 is connected to each gate of the transistors MH and ML, so as to separately control the gate voltages of the transistors MH and ML, thereby sets the transistors MH and ML separately to ON or OFF. The second signal processing circuit 1210 is driven on the basis of the power supply voltage VCC2 with respect to the potential of the ground GND2. However, the second signal processing circuit 1210 is connected not only to the power supply terminal PIN2 and the ground terminal GNDb but also to the negative power supply terminal NEG, so as to supply the voltage VEE2 of the negative power supply terminal NEG to the gate of the transistor ML, and hence can appropriately set the transistor ML to OFF.

On the basis of the control signal Dout and the signal supplied from the overvoltage detection circuit 1220 (details will be described later), the second signal processing circuit 1210 sets the state of the driver DRV to be an output high state, an output low state, or a both OFF state (Hi-Z state). In the output high state of the driver DRV, the transistor MH is ON while the transistor ML is OFF. In the output low state of the driver DRV, the transistor MH is OFF while the transistor ML is ON. In the both OFF state of the driver DRV, the transistors MH and ML are both OFF.

When the state of the driver DRV is the output high state, positive charges are supplied to the gate of the target transistor MO from the application terminal of the power supply voltage VCC2, via the transistor MH and the output terminal OUT through the wiring WR3, and thus the gate voltage of the target transistor MO is increased to the power supply voltage VCC2. When the state of the driver DRV is the output low state, positive charges are pulled into the negative power supply terminal NEG from the gate of the target transistor MO, through the wiring WR3 via the output terminal OUT and the transistor ML, and thus the gate voltage of the target transistor MO is decreased to the voltage VEE2. In this way, the driver DRV performs input and output of charges from and to the gate of the target transistor MO through the output terminal OUT and the wiring WR3, so as to drive the gate of the target transistor MO (controls the gate voltage). When the state of the driver DRV is the both OFF state, current is not generated between the driver DRV and the gate of the target transistor MO.

When the gate voltage of the target transistor MO is equal to the power supply voltage VCC2, the target transistor MO is in ON state. When the gate voltage of the target transistor MO is equal to the voltage VEE2, the target transistor MO is in OFF state. In other words, in accordance with the control signal Dout, using the driver DRV, the second signal processing circuit 1210 supplies the power supply voltage VCC2 (high side voltage) higher than the potential of the ground GND2 to the wiring WR3, so as to control the target transistor MO to be ON, while it supplies the voltage VEE2 (low side voltage) lower than the power supply voltage VCC2 (high side voltage) to the wiring WR3, so as to control the target transistor MO to be OFF. However, the state of the target transistor MO is switched from OFF state to ON state in the middle of the period where the gate voltage of the target transistor MO is increasing from the voltage VEE2 to the power supply voltage VCC2, due to switching of the state of the driver DRV from the output low state to the output high state. Similarly, the state of the target transistor MO is switched from ON state to OFF state in the middle of the period where the gate voltage of the target transistor MO is decreasing from the power supply voltage VCC2 to the voltage VEE2, due to switching of the state of the driver DRV from the output high state to the output low state. In order that desired OFF characteristics can be obtained in the target transistor MO in the period where the target transistor MO is to be controlled to OFF, or in order that the target transistor MO can promptly go from ON state to OFF state when the target transistor MO is to be switched from ON state to OFF state, the negative voltage VEE2 is introduced in the system of FIG. 11.

The overvoltage detection circuit 1220 is connected to the ground terminal GNDb and the negative power supply terminal NEG, so as to detect presence or absence of occurrence of abnormality that the voltage VEE2 is excessively decreased with respect to the potential of the ground GND2 (hereinafter, referred to as a negative voltage abnormality). The overvoltage detection circuit 1220 outputs an overvoltage signal S_OVLO that indicates a detection result of presence or absence of occurrence of the negative voltage abnormality to the second signal processing circuit 1210, and controls the state of the protection switching element 1230 on the basis of the detection result of presence or absence of occurrence of the negative voltage abnormality. The overvoltage signal S_OVLO is a binary signal having high level or low level. The overvoltage signal S_OVLO of high level may have the potential of the power supply voltage VCC2, while the overvoltage signal S_OVLO of low level may have the potential of the ground GND2. In the overvoltage signal S_OVLO, one of high level and low level is assigned to an asserted state (active state), and the other is assigned to a negated state (inactive state). Here, it is supposed that the overvoltage signal S_OVLO of low level is in the asserted state, and that the overvoltage signal S_OVLO of high level is in the negated state (although the opposite relationship is possible).

The overvoltage detection circuit 1220 compares a difference voltage V_DIF between the voltage of the ground GND2 and the voltage VEE2 with a threshold voltage Vth_OVLO. Here, it is supposed that the difference voltage V_DIF has a positive polarity when the voltage VEE2 is low with respect to the potential of the ground GND2. It may be possible to understand that the absolute value of the difference between the voltage of the ground GND2 and the voltage VEE2 is the difference voltage V_DIF. A threshold voltage Vth_OVLO has a predetermined positive voltage value (e.g., 8 V). In principle, the overvoltage detection circuit 1220 sets the overvoltage signal S_OVLO to high level (sets the same to the negated state), and maintains the overvoltage signal S_OVLO at high level as long as the difference voltage V_DIF is maintained to be lower than the threshold voltage Vth_OVLO. However, when detecting that the difference voltage V_DIF is equal to or higher than the threshold voltage Vth_OVLO, the overvoltage detection circuit 1220 outputs the overvoltage signal S_OVLO in the asserted state (i.e., the overvoltage signal S_OVLO of low level). That the difference voltage V_DIF is equal to or higher than the threshold voltage Vth_OVLO corresponds to that the voltage VEE2 is lower than the voltage of the wiring WR2 by the threshold voltage Vth_OVLO or more, and the state where the difference voltage V_DIF is equal to or higher than the threshold voltage Vth_OVLO is the above negative voltage abnormality.

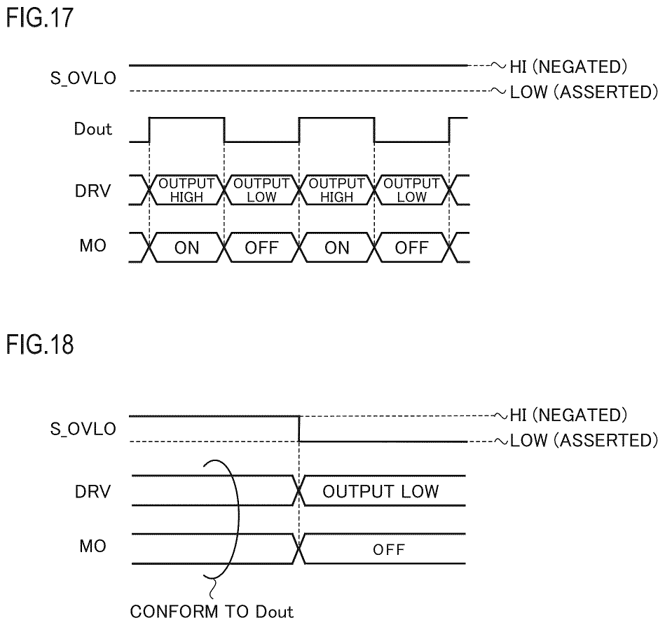

As illustrated in FIG. 17, on the condition that the overvoltage signal S_OVLO is in the negated state, the second signal processing circuit 1210 sets the driver DRV to the output high state during the high level period of the control signal Dout, so as to supply the power supply voltage VCC2 to the wiring WR3 (to supply the same to the gate of the target transistor MO), and thus controls the target transistor MO to be ON. On the condition that the overvoltage signal S_OVLO is in the negated state, the second signal processing circuit 1210 sets the driver DRV to the output low state during the low level period of the control signal Dout, so as to supply the voltage VEE2 to the wiring WR3 (to supply the same to the gate of the target transistor MO), and thus controls the target transistor MO to be OFF. In other words, on the condition that the overvoltage signal S_OVLO is in the negated state, the second signal processing circuit 1210 switches the state of the driver DRV between the output high state and the output low state, in accordance with the control signal Dout, so as to switch the target transistor MO between ON and OFF. However, the switching between the output high state and the output low state is a concept including that the state of the driver DRV is set to the both OFF state during a minute dead time, in order to prevent occurrence of a through current during the switching process, and a circuit that inserts the dead time may be included in the second signal processing circuit 1210.

Originally, the difference voltage V_DIF described above should have a voltage value within a voltage range given in the specification of the signal transmission device 1000 (e.g., 5 volts or lower). However, an abnormality in the negative voltage generation circuit 1600, or an abnormality in another circuit that affects the difference voltage V_DIF may cause the difference voltage V_DIF to be too large. It is not desired to set the target transistor MO to be ON so that current is supplied to the load LD when an abnormality has occurred in a certain circuit. In consideration of this, the signal transmission device 1000 has a VEE2_OVLO function. The VEE2_OVLO function is a function of supplying the voltage VEE2 to the gate of the target transistor MO by setting the driver DRV to the output low state, regardless of the control signal Dout (therefore, regardless of the control signal Din), when it is detected that the difference voltage V_DIF is equal to or higher than the threshold voltage Vth_OVLO. The VEE2_OVLO function is realized by the second signal processing circuit 1210 responding to the overvoltage signal S_OVLO from the overvoltage detection circuit 1220. In other words, as illustrated in FIG. 18, while the overvoltage signal S_OVLO in the asserted state (the overvoltage signal S_OVLO of low level) is output from the overvoltage detection circuit 1220, the second signal processing circuit 1210 sets the driver DRV to the output low state regardless of the control signal Dout, so as to supply the voltage VEE2 to the wiring WR3 (therefore, to supply the same to the gate of the target transistor MO), thereby sets the target transistor MO to be OFF, i.e., it performs a protection operation.

The VEE2_OVLO function is useful for protection and the like of the load LD when the negative voltage abnormality occurs. However, if the voltage VEE2 is supplied to the gate of the target transistor MO in a state where the difference voltage V_DIF is quite large, the gate-emitter voltage of the target transistor MO may exceed the withstand voltage. In consideration of this, the signal transmission device 1000 is provided with the protection switching element 1230. As illustrated in FIG. 11, the protection switching element 1230 is disposed between the ground terminal GNDb and the negative power supply terminal NEG (in other words, it is disposed between the wirings WR2 and WR4).

The overvoltage detection circuit 1220 supplies a signal SW_CNT to the protection switching element 1230 so as to set the protection switching element 1230 to be ON or OFF. The signal SW_CNT has the value of “1” or “0”, and a level of the signal SW_CNT having the value of “1” is different from a level of the signal SW_CNT having the value of “0”. When the signal SW_CNT has the value of “1”, the protection switching element 1230 becomes ON, while when the signal SW_CNT has the value of “0”, the protection switching element 1230 becomes OFF.

Only when the protection switching element 1230 is ON, the ground terminal GNDb and the negative power supply terminal NEG are conductive to each other through the protection switching element 1230. During the ON period of the protection switching element 1230, the magnitude of the voltage between the ground terminal GNDb and the negative power supply terminal NEG (i.e., the difference voltage V_DIF) is maintained at a voltage sufficiently lower than the threshold voltage Vth_OVLO. During the OFF period of the protection switching element 1230, the protection switching element 1230 has no influence on the voltage between the ground terminal GNDb and the negative power supply terminal NEG.

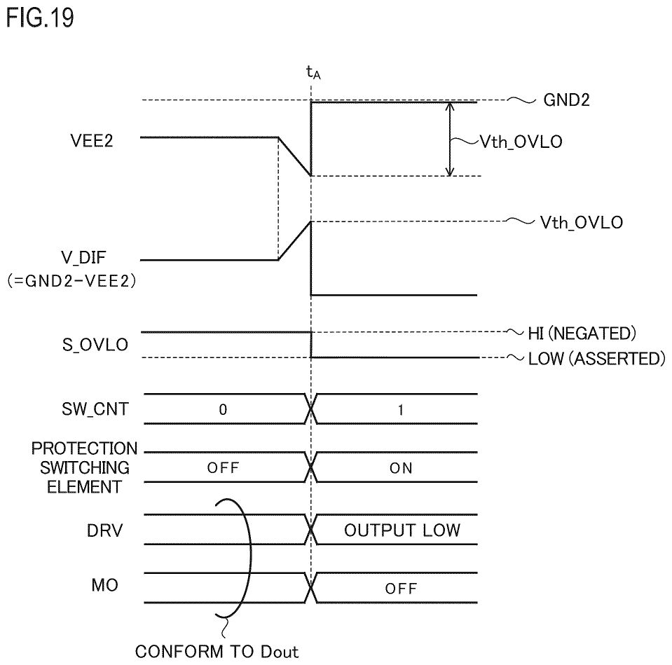

FIG. 19 illustrates a timing chart for explaining an operation when detecting the voltage abnormality. FIG. 19 illustrates, in order from top to bottom, a waveform of the voltage VEE2, a waveform of the difference voltage V_DIF, a waveform of the overvoltage signal S_OVLO, a change in a value of the signal SW_CNT, a change in the state of the protection switching element 1230, a change in the state of the driver DRV, and a change in the state of the target transistor MO. As illustrated in FIG. 19, during the high level period of the overvoltage signal S_OVLO (i.e., during the period where the overvoltage signal S_OVLO is in the negated state), the overvoltage detection circuit 1220 supplies the signal SW_CNT having the value of “0” to the protection switching element 1230, so as to set the protection switching element 1230 to be OFF. During the low level period of the overvoltage signal S_OVLO (i.e., during the period where the overvoltage signal S_OVLO is in the asserted state), the overvoltage detection circuit 1220 supplies the signal SW_CNT having the value of “1” to the protection switching element 1230, so as to set the protection switching element 1230 to be ON. FIG. 19 illustrates a manner in which the overvoltage signal S_OVLO is switched from the negated state to the asserted state, as a result where the difference voltage V_DIF has reached the threshold voltage Vth_OVLO, after the difference voltage V_DIF increases from the state where the difference voltage V_DIF is maintained to be lower than the threshold voltage Vth_OVLO.

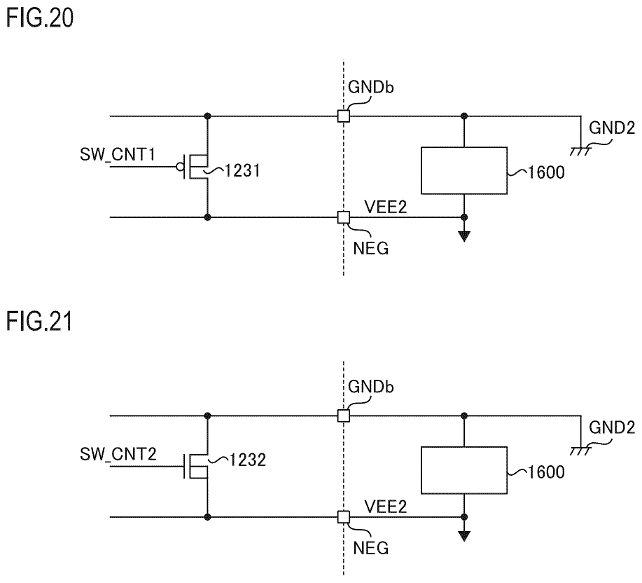

As illustrated in FIG. 20, a protection transistor 1231 that is a P-channel type MOSFET can be used as the protection switching element 1230. In this case, the source of the protection transistor 1231 is connected to the ground terminal GNDb, the drain of the protection transistor 1231 is connected to the negative power supply terminal NEG, and the gate of the protection transistor 1231 is supplied with a signal SW_CNT1 as the signal SW_CNT. If the protection transistor 1231 is the protection switching element 1230, when the signal SW_CNT1 of high level as the signal SW_CNT having the value of “0” is supplied to the gate of the protection transistor 1231, the protection transistor 1231 becomes OFF, and when the signal SW_CNT1 of low level as the signal SW_CNT having the value of “1” is supplied to the gate of the protection transistor 1231, the protection transistor 1231 becomes ON.

Here, the signal SW_CNT1 of high level has the potential of the ground GND2 or has a potential higher than the potential of the ground GND2. The signal SW_CNT1 of low level has a potential lower than the potential of the ground GND2, and the difference between the potential of the signal SW_CNT1 of low level and the potential of the ground GND2 is larger than the absolute value of the gate threshold value voltage of the protection transistor 1231. The signal SW_CNT1 of low level may have the potential of the voltage VEE2. In this case, during the low level period of the overvoltage signal S_OVLO, the gate and drain of the protection transistor 1231 are short-circuited, and hence the voltage corresponding to the absolute value of the gate threshold value voltage of the protection transistor 1231 remains between the ground terminal GNDb and the negative power supply voltage NEG. As a result, the voltage corresponding to the absolute value of the gate threshold value voltage of the protection transistor 1231 is applied between the gate and emitter of the target transistor MO. However, the magnitude of the gate threshold value voltage of the protection transistor 1231 is sufficiently smaller than the threshold voltage Vth_OVLO as well as the withstand voltage between the gate and emitter of the target transistor MO, and hence there is no problem.

Alternatively, as illustrated in FIG. 21, a protection transistor 1232 that is an N-channel type MOSFET can be used as the protection switching element 1230. In this case, the drain of the protection transistor 1232 is connected to the ground terminal GNDb, the source of the protection transistor 1232 is connected to the negative power supply terminal NEG, and the gate of the protection transistor 1232 is supplied with a signal SW_CNT2 as the signal SW_CNT. If the protection transistor 1232 is the protection switching element 1230, when the signal SW_CNT2 of low level as the signal SW_CNT having the value of “0” is supplied to the gate of the protection transistor 1232, the protection transistor 1232 becomes OFF, and when the signal SW_CNT2 of high level as the signal SW_CNT having the value of “1” is supplied to the gate of the protection transistor 1232, the protection transistor 1232 becomes ON.

Here, the signal SW_CNT2 of low level has the potential of the voltage VEE2, and the signal SW_CNT2 of high level has the potential of the power supply voltage VCC2. The signal SW_CNT2 of high level may have the potential of the ground GND2. If the signal SW_CNT2 of high level has the potential of the ground GND2, during the low level period of the overvoltage signal S_OVLO, the gate and drain of the protection transistor 1232 are short-circuited, and hence a voltage corresponding to the gate threshold value voltage of the protection transistor 1232 remains between the ground terminal GNDb and the negative power supply voltage NEG. As a result, a voltage corresponding to the gate threshold value voltage of the protection transistor 1232 is applied between the gate and emitter of the target transistor MO. However, the gate threshold value voltage of the protection transistor 1232 is sufficiently smaller than the threshold voltage Vth_OVLO as well as the withstand voltage between the gate and emitter of the target transistor MO, and hence there is no problem.

In the example of FIG. 19, after the period where the overvoltage signal S_OVLO in the negated state is output from the overvoltage detection circuit 1220, at time point ta, the state where “V_DIF<Vth_OVLO” holds is changed to the state where “V_DIF≥Vth_OVLO” holds. In response to this change, the overvoltage detection circuit 1220 changes the state of the overvoltage signal S_OVLO from the negated state to the asserted state. After changing the state of the overvoltage signal S_OVLO from the negated state to the asserted state, the overvoltage detection circuit 1220 maintains output of the overvoltage signal S_OVLO in the asserted state until a predetermined cancellation condition is satisfied. When the cancellation condition is satisfied, the state of the overvoltage signal S_OVLO is restored to the negated state. If the overvoltage signal S_OVLO is the asserted state, the protection switching element 1230 is maintained at ON state. When restoring the overvoltage signal S_OVLO to the negated state, the overvoltage detection circuit 1220 restores the value of the signal SW_CNT from “1” to “0”, so as to restore the state of the protection switching element 1230 from ON state to OFF state.

For instance, the cancellation condition may be a condition that is satisfied when a rising edge occurs in the control signal Dout. In this case, after the state of the overvoltage signal S_OVLO is switched from the negated state to the asserted state at time point ta, until a rising edge occurs in the control signal Dout, the overvoltage signal S_OVLO is maintained at the asserted state, and the protection switching element 1230 is maintained at ON state. Further, after time point ta, when a rising edge occurs in the control signal Dout, the overvoltage signal S_OVLO is switched from the asserted state to the negated state, and the protection switching element 1230 is switched from the ON state to OFF state. It is supposed that a signal indicating that a rising edge has occurred in the control signal Dout is transmitted from the second signal processing circuit 1210 to the overvoltage detection circuit 1220.

In the case where the cancellation condition is satisfied when a rising edge occurs in the control signal Dout, if the negative voltage abnormality is cancelled after time point ta, afterward it is possible to set the target transistor MO to be ON or OFF, by supplying the signal transmission device 1000 with the control signal Din that changes between high level and low level from the MPU 1400. Even if the overvoltage signal S_OVLO is restored to the negated state when the cancellation condition is satisfied, if the negative voltage abnormality continues to arise after time point t_{A}, the overvoltage signal S_OVLO is promptly set to the asserted state.

Other than that, the cancellation condition is arbitrary. It may be possible that the cancellation condition is satisfied when a predetermined cancellation signal is input to a specific external terminal provided to the signal transmission device 1000. Alternatively, it may be possible that the cancellation condition is satisfied when a predetermined cancellation command signal is input from the MPU 1400 to the signal transmission device 1000.

According to the signal transmission device 1000 illustrated in FIG. 11, it is possible to prevent an excessive voltage from being applied to the gate-emitter voltage of the target transistor MO, while realizing the VEE2_OVLO function.

### Modification etc.

An application technique, a modified technique, or supplementary note of the above system SYS or the signal transmission device 1000 is described below.

In the signal transmission device 1000 of FIG. 11, it can be considered that the second signal processing circuit 1210 and the driver DRV constitute a control circuit. In this case, the control signal Din or Dout can be regarded as an input control signal. In accordance with the input control signal (Din, Dout), the control circuit (1210, DRV) supplies the power supply voltage VCC2 (high side voltage) to the wiring WR3 so as to control the target transistor MO to be ON, or supplies the voltage VEE2 (low side voltage) lower than the power supply voltage VCC2 to the wiring WR3 so as to control the target transistor MO to be OFF.

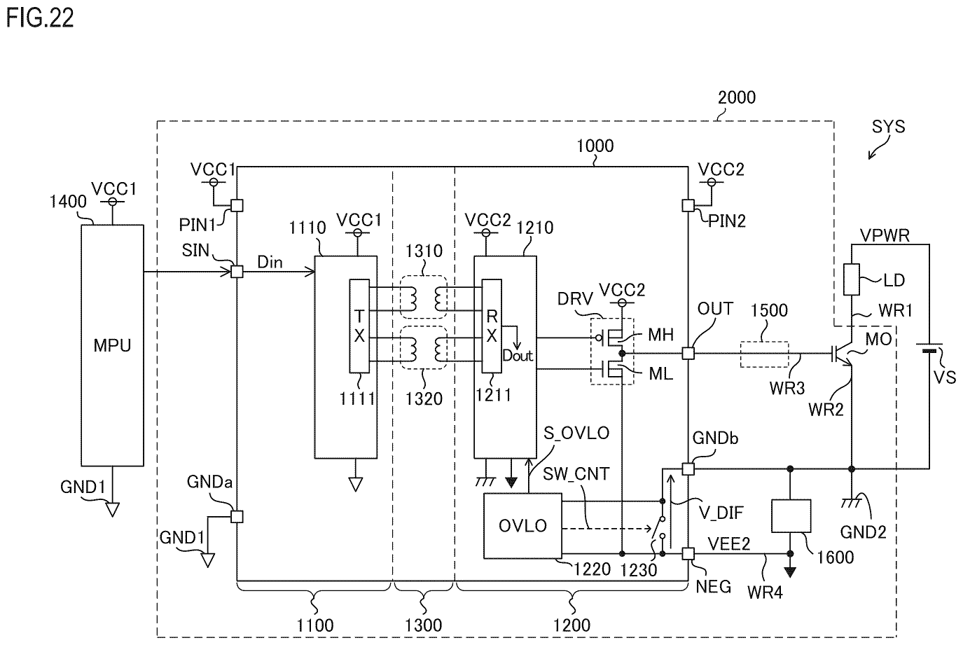

As illustrated in FIG. 22, the system SYS includes a switching device 2000. The switching device 2000 can be understood to be a device obtained by eliminating the MPU 1400, the load LD, and the voltage source VS from the system SYS of FIG. 11, and therefore includes at least the signal transmission device 1000, the target transistor MO, the resistor circuit 1500, and the negative voltage generation circuit 1600 as its structural elements. However, it may be possible to consider that the negative voltage generation circuit 1600 is disposed outside of the switching device 2000 and is connected to the switching device 2000.

It may be possible to dispose two switching devices 2000, and to form a half bridge circuit by connecting the target transistor MO in the first the switching device 2000 and the target transistor MO in the second switching device 2000 in series. In this case, the same MPU 1400 may be connected to the first and second signal transmission devices 1000. The source potential of the target transistor MO in the i-th switching device 2000 functions as the ground GND2 in the i-th switching device 2000 (here, i-th means first or second).

It may be possible to form a motor drive system having six switching devices 2000, so as to drive a three-phase motor. In this case, the target transistors MO in the first and second switching devices 2000 can be used respectively as an upper arm and a lower arm of the U-phase, and the target transistors MO in the third and fourth switching devices 2000 can be used respectively as an upper arm and a lower arm of the V-phase, and the target transistors MO in the fifth and sixth switching devices 2000 can be used respectively as an upper arm and a lower arm of the W-phase. Further, it is sufficient to control supply currents to a U-phase coil, a V-phase coil, and a W-phase coil of the three-phase motor, by ON-OFF control of the six target transistors MO. In the motor drive system, the same MPU 1400 may be connected to the six signal transmission devices 1000. The source potential of the target transistor MO in the i-th switching device 2000 functions as the ground GND2 in the i-th switching device 2000 (here, i-th means one of first to sixth).

The system SYS of FIG. 11, or an arbitrary system including the system SYS (the above motor drive system or the like) can be mounted in an arbitrary electrical device. The electrical device may be an electrical component mounted in a vehicle such as an automobile, or may be a computer device, a home appliance device, or an industrial device.

As to the signal transmission device 1000 having the structure as illustrated in FIG. 11, the technique related to the VEE2_OVLO function is described above, and this technique may be applied to an arbitrary semiconductor device. In other words, for example, it may be possible to constitute a semiconductor device obtained by eliminating the primary side circuit 1100 and the insulation circuit 1300 from the signal transmission device 1000 of FIG. 11 (hereinafter, referred to as a modified semiconductor device). In the modified semiconductor device, the control signal Din from the MPU 1400 is the control signal Dout.

For an arbitrary signal or voltage, the relationship between high level and low level can be opposite to that described above, in a form that does not impair the spirit of the above description.

The type of the channel of the field-effect transistor (FET) described in the above embodiment is merely an example. The type of the channel of an arbitrary FET can be changed between the P-channel type and the N-channel type, in a form that does not impair the spirit of the above description.

Unless any inconvenience arises, the above arbitrary transistor may be any type of transistor. For instance, an arbitrary transistor described as a MOSFET can be replaced by a junction type FET, an insulated gate bipolar transistor (IGBT), or a bipolar transistor, unless any inconvenience arises. An arbitrary transistor has a first conductive electrode, a second conductive electrode, and a control electrode. In an FET, one of the first and second conductive electrodes is the drain, while the other is the source, and the control electrode is the gate. In an IGBT, one of the first and second conductive electrodes is the collector, while the other is the emitter, and the control electrode is the gate. In a bipolar transistor that does not belong to IGBT, one of the first and second conductive electrodes is a collector, while the other is an emitter, and the control electrode is the base.

When the N-channel type MOSFET is used as the target transistor MO, the drain of the target transistor MO is connected to the wiring WR1, and the source of the target transistor MO is connected to the wiring WR2. The gate of the target transistor MO is connected to the wiring WR3 in the same manner regardless whether the target transistor MO is an IGBT or a MOSFET.

The embodiment of the present disclosure can be appropriately and variously modified within the scope of the technical concept recited in the claims. The above embodiment is merely an example of the embodiment of the present disclosure, and meanings of the present disclosure and terms of the structural elements are not limited to those described in the above embodiment. Specific numeric values shown in the above description are merely examples, and they can be changed to various values as a matter of course.

### Additional Notes

Additional notes are given below for the present disclosure, in which specific structural examples are shown in the above embodiment.

A semiconductor device according to one aspect of the present disclosure (see FIG. 11) is a semiconductor device (1100) configured to control a state of a target transistor (MO) having a first conductive electrode, a second conductive electrode, and a control electrode, the target transistor being configured so that the first conductive electrode is connected to a first wiring (WR1), the second conductive electrode is connected to a second wiring (WR2), and the control electrode is connected to a third wiring (WR3). The semiconductor device comprises a control circuit (1210, DRV) configured to respond to an input control signal (Din, Dout) so as to supply a high side voltage (VCC2) higher than a voltage of the second wiring to the third wiring, thereby controlling the target transistor to be ON, or to supply a low side voltage (VEE2) lower than the high side voltage to the third wiring, thereby controlling the target transistor to be OFF; an overvoltage detection circuit (1220) configured to output an overvoltage signal (S_OVLO) in an asserted state, if the low side voltage is lower than the voltage of the second wiring by a predetermined threshold voltage (Vth_OVLO) or more; and a protection switching element (1230) disposed between the second wiring and a fourth wiring (WR4) applied with the low side voltage. When the overvoltage signal in the asserted state is output from the overvoltage detection circuit, the control circuit performs an operation of supplying the low side voltage to the third wiring regardless of the input control signal, and the overvoltage detection circuit sets the protection switching element to be ON (first structure).

In this way, while having a function of cutting off the target transistor when the low side voltage is excessively low with respect to the voltage of the second wiring, it is prevented that an excessive voltage is applied between the control electrode and the second conductive electrode of the target transistor, and hence the target transistor is protected.

The semiconductor device according to the above first structure (see FIG. 11 and FIG. 19) may have a structure (second structure), in which the overvoltage detection circuit outputs the overvoltage signal in the asserted state or a negated state in accordance with a difference (V_DIF) between the voltage of the second wiring and the low side voltage, and after the period where the overvoltage signal in the negated state is output from the overvoltage detection circuit, when the state, where the difference between the voltage of the second wiring and the low side voltage is less than the threshold voltage, changes to the state where the low side voltage is lower than the voltage of the second wiring by the threshold voltage or more (at time point ta in FIG. 19), the overvoltage detection circuit changes a state of the overvoltage signal to the asserted state.

The semiconductor device according to the above second structure may have a structure (third structure), in which the overvoltage detection circuit continues to output the overvoltage signal in the asserted state, after changing the state of the overvoltage signal to the asserted state until a predetermined cancellation condition is satisfied.

The semiconductor device according to the above third structure may have a structure (fourth structure), in which during the period where the state of the overvoltage signal is the negated state, the control circuit supplies the high side voltage to the third wiring so as to control the target transistor to be ON if the input control signal has a first level, and supplies the low side voltage to the third wiring so as to control the target transistor to be OFF if the input control signal has a second level, and the cancellation condition is satisfied when the input control signal changes from the second level to the first level.

The semiconductor device according to any one of the above first to fourth structures (see FIG. 11) may have a structure (fifth structure), in which the control circuit includes a driver (DRV) having a high side transistor (MH) disposed between an application terminal of the high side voltage and the third wiring, and a low side transistor (ML) disposed between the third wiring and the fourth wiring, and sets the high side transistor to be ON while sets the low side transistor to be OFF, so as to supply the high side voltage to the third wiring, and sets the high side transistor to be OFF while sets the low side transistor to be ON, so as to supply the low side voltage to the third wiring.

The semiconductor device according to any one of the above first to fifth structures may have a structure (sixth structure), in which the target transistor is an insulation gate bipolar transistor, and the first conductive electrode, the second conductive electrode, and the control electrode are respectively collector, emitter, and gate.

The semiconductor device according to any one of the above first to fifth structures may have a structure (seventh structure), in which the target transistor is a field-effect transistor, and the first conductive electrode, the second conductive electrode, and the control electrode are respectively drain, source, and gate.

The semiconductor device according to any one of the above first to seventh structures may have a structure (eighth structure), in which the semiconductor device is a signal transmission device (1000) disposed between an external device (1400) and the target transistor, and comprises primary side circuit (1100) configured to receive a primary side control signal (Din) from the external device; a secondary side circuit (1200) configured to drive the control electrode of the target transistor; and an insulation circuit (1300) configured to insulate in a DC manner between the primary side circuit and the secondary side circuit, while transmitting the primary side control signal as a secondary side control signal to the secondary side circuit. The control circuit, the overvoltage detection circuit, and the protection switching element are disposed in the secondary side circuit, and the primary side control signal or the secondary side control signal is the input control signal.

A switching device according to one aspect of the present disclosure comprises the semiconductor device according to any one of the above first to eighth structures, and the target transistor (ninth structure).

What is claimed is:

1. A semiconductor device configured to control a state of a target transistor having a first conductive electrode, a second conductive electrode, and a control electrode, the target transistor being configured so that the first conductive electrode is connected to a first wiring, the second conductive electrode is connected to a second wiring, and the control electrode is connected to a third wiring, the semiconductor device comprising:
a control circuit configured to respond to an input control signal so as to supply a high side voltage higher than a voltage of the second wiring to the third wiring, thereby controlling the target transistor to be ON, or to supply a low side voltage lower than the high side voltage to the third wiring, thereby controlling the target transistor to be OFF;
an overvoltage detection circuit configured to output an overvoltage signal in an asserted state, if the low side voltage is lower than the voltage of the second wiring by a predetermined threshold voltage or more; and
a protection switching element disposed between the second wiring and a fourth wiring applied with the low side voltage, wherein
when the overvoltage signal in the asserted state is output from the overvoltage detection circuit, the control circuit performs an operation of supplying the low side voltage to the third wiring regardless of the input control signal, and the overvoltage detection circuit sets the protection switching element to be ON.

2. The semiconductor device according to claim 1, wherein
the overvoltage detection circuit outputs the overvoltage signal in the asserted state or a negated state in accordance with a difference between the voltage of the second wiring and the low side voltage, and
after the period where the overvoltage signal in the negated state is output from the overvoltage detection circuit, when the state where the difference between the voltage of the second wiring and the low side voltage is less than the threshold voltage changes to the state where the low side voltage is lower than the voltage of the second wiring by the threshold voltage or more, the overvoltage detection circuit changes a state of the overvoltage signal to the asserted state.

3. The semiconductor device according to claim 2, wherein the overvoltage detection circuit continues to output the overvoltage signal in the asserted state, after changing the state of the overvoltage signal to the asserted state until a predetermined cancellation condition is satisfied.

4. The semiconductor device according to claim 3, wherein
during the period where the state of the overvoltage signal is the negated state, the control circuit supplies the high side voltage to the third wiring so as to control the target transistor to be ON if the input control signal has a first level, and supplies the low side voltage to the third wiring so as to control the target transistor to be OFF if the input control signal has a second level, and
the cancellation condition is satisfied when the input control signal changes from the second level to the first level.

5. The semiconductor device according to claim 1, wherein the control circuit includes a driver having a high side transistor disposed between an application terminal of the high side voltage and the third wiring, and a low side transistor disposed between the third wiring and the fourth wiring, and sets the high side transistor to be ON while sets the low side transistor to be OFF, so as to supply the high side voltage to the third wiring, and sets the high side transistor to be OFF while sets the low side transistor to be ON, so as to supply the low side voltage to the third wiring.

6. The semiconductor device according to claim 1, wherein the target transistor is an insulation gate bipolar transistor, and the first conductive electrode, the second conductive electrode, and the control electrode are respectively collector, emitter, and gate.

7. The semiconductor device according to claim 1, wherein the target transistor is a field-effect transistor, and the first conductive electrode, the second conductive electrode, and the control electrode are respectively drain, source, and gate.

8. The semiconductor device according to claim 1, which is a signal transmission device disposed between an external device and the target transistor, comprising:
a primary side circuit configured to receive a primary side control signal from the external device;
a secondary side circuit configured to drive the control electrode of the target transistor; and
an insulation circuit configured to insulate in a DC manner between the primary side circuit and the secondary side circuit, while transmitting the primary side control signal as a secondary side control signal to the secondary side circuit, wherein
the control circuit, the overvoltage detection circuit, and the protection switching element are disposed in the secondary side circuit, and the primary side control signal or the secondary side control signal is the input control signal.

9. A switching device comprising:
the semiconductor device according to claim 1; and
the target transistor.
